(19) United States
(12) Patent Application Publication
(10) Pub. No.: US 2025/0079322 A1
(43) Pub. Date: Mar. 6, 2025

(54) STACKED WIRING SUBSTRATE AND SEMICONDUCTOR DEVICE

(71) Applicant: SHINKO ELECTRIC INDUSTRIES CO., LTD., Nagano-shi (JP)

(72) Inventor: Kosuke TSUKAMOTO, Osaka (JP)

(21) Appl. No.: 18/817,574

(22) Filed: Aug. 28, 2024

(30) Foreign Application Priority Data
Sep. 1, 2023 (JP) 2023-142280

(51) Int. Cl. H01L 23/538; H01L 23/00; H01L 25/065

(52) U.S. Cl. CPC H01L 23/5385; H01L 23/5386; H01L 24/16; H01L 24/32; H01L 24/73; H01L 25/0655; H01L 2224/16227; H01L 2224/32225; H01L 2224/73204

(57) ABSTRACT

A stacked wiring substrate includes a first wiring substrate and a second wiring substrate mounted on the first wiring substrate. The first wiring substrate includes a first wiring layer, a first insulating layer covering the first wiring layer, a second wiring layer stacked on an upper surface of the first insulating layer and electrically connected to the first wiring layer, a second insulating layer stacked on the upper surface of the first insulating layer and covering the second wiring layer, and a first electrode pad stacked on an upper surface of the second insulating layer and electrically connected to the second wiring layer. The second wiring substrate includes a wiring structure having a higher wiring density than the first wiring substrate, and a second electrode pad connected to the first electrode pad. The second insulating layer is thinner than the first insulating layer.

### CROSS-REFERENCE TO RELATED APPLICATIONS

This application is based upon and claims the benefit of priority from prior Japanese Patent Application No. 2023-142280, filed on Sep. 1, 2023, the entire contents of which are incorporated herein by reference.

### BACKGROUND

### 1. Field

The following description relates to a stacked wiring substrate, a semiconductor device, and a method for manufacturing a stacked wiring substrate.

### 2. Description of Related Art

Wiring substrates for mounting electronic components, such as semiconductor chips, are available in various shapes and configurations. A typical wiring substrate includes a fine wiring structure with wiring layers having a relatively high wiring density. Japanese Laid-Open Patent Publication No. 2020-47735 describes a stacked wiring substrate including a first wiring substrate, which is a base substrate, and a second wiring substrate, which is mounted on the first wiring substrate and has a fine wiring structure. In such a stacked wiring substrate, electrode pads of the first wiring substrate are joined to electrode pads of the second wiring substrate by a solder layer so that the second wiring substrate is mounted on the first wiring substrate.

### SUMMARY

As the semiconductor chips become further sophisticated, there is a need to narrow the distance between the consecutive electrode pads in the stacked wiring substrate.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a stacked wiring substrate includes a first wiring substrate and a second wiring substrate mounted on the first wiring substrate. The first wiring substrate includes a first wiring layer, a first insulating layer, a second wiring layer, a second insulating layer, and a first electrode pad. The first insulating layer coves the first wiring layer. The second wiring layer is stacked on an upper surface of the first insulating layer and is electrically connected to the first wiring layer. The second insulating layer is stacked on the upper surface of the first insulating layer and covers the second wiring layer. The first electrode pad is stacked on an upper surface of the second insulating layer and is electrically connected to the second wiring layer. The second wiring substrate includes a wiring structure and a second electrode pad. The wiring structure has a higher wiring density than the first wiring substrate. The second electrode pad is connected to the first electrode pad. A thickness of the second insulating layer is less than a thickness of the first insulating layer.

Other features and aspects will be apparent from the following detailed description, the drawings, and the claims.

### BRIEF DESCRIPTION OF THE DRAWINGS

FIG. 1 is a schematic cross-sectional view of a stacked wiring substrate in accordance with a first embodiment.

FIG. 2 is a cross-sectional view enlarging part of the stacked wiring substrate illustrated in FIG. 1.

FIG. 3 is a schematic cross-sectional view of a semiconductor device including the stacked wiring substrate illustrated in FIG. 1.

FIGS. 4, 5, 6, 7, 8, 9, 10, 11, and 12 are schematic cross-sectional views illustrating a method for manufacturing the stacked wiring substrate illustrated in FIG. 1.

FIG. 13 is a schematic cross-sectional view of a stacked wiring substrate in accordance with a second embodiment.

FIG. 14 is a cross-sectional view enlarging part of the stacked wiring substrate illustrated in FIG. 13.

FIGS. 15, 16, 17, 18, 19, and 20 are schematic cross-sectional views illustrating a method for manufacturing the stacked wiring substrate illustrated in FIG. 13.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

Embodiments will now be described with reference to the drawings. In the accompanying drawings, elements are illustrated for simplicity and clarity and have not necessarily been drawn to scale. To facilitate understanding, hatching lines may not be shown or may be replaced by shadings in the cross-sectional views.

### First Embodiment

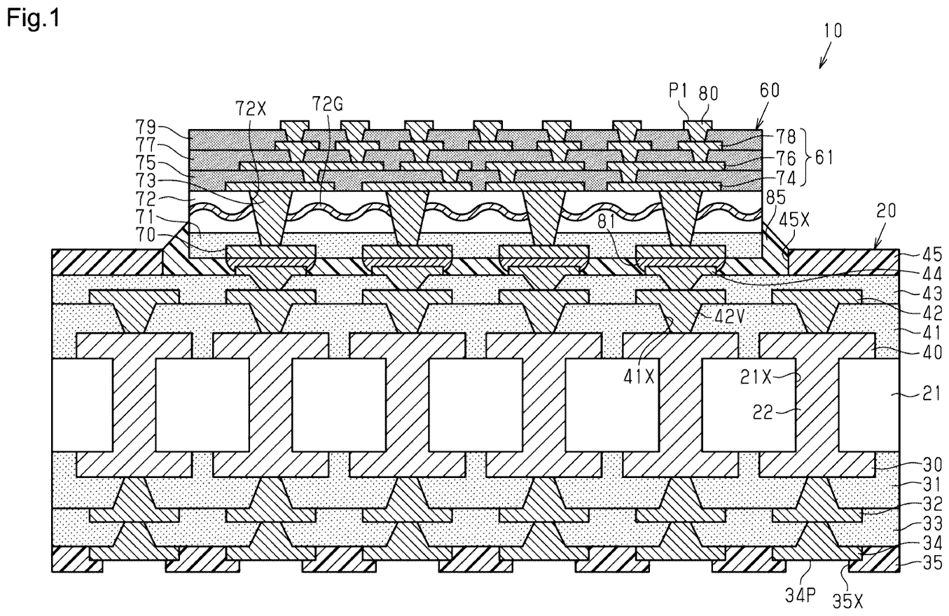

A first embodiment will now be described with reference to FIGS. 1 to 12.

### Overall Configuration of Stacked Wiring Substrate 10

As illustrated in FIG. 1, a stacked wiring substrate 10 includes a first wiring substrate 20 and a second wiring substrate 60 mounted on the first wiring substrate 20. The stacked wiring substrate 10 includes, for example, an underfill resin 85 formed in a gap between the first wiring substrate 20 and the second wiring substrate 60.

### Structure of First Wiring Substrate 20

The first wiring substrate 20 includes a core layer 21. The core layer 21 is located, for example, at a central part of the first wiring substrate 20 in a thickness-wise direction. The material of the core layer 21 may be, for example, a glass epoxy substrate obtained by impregnating a glass cloth (glass woven cloth), which is a reinforcement material, with a non-photosensitive thermosetting resin, which includes an epoxy resin as a main component, and curing the resin. The reinforcement material is not limited to a glass cloth and may be, for example, a glass non-woven cloth, an aramid woven cloth, an aramid non-woven cloth, a liquid crystal polymer (LCP) woven cloth, or an LCP non-woven cloth. The thermosetting insulating resin is not limited to an epoxy resin and may be, for example, a resin material such as an imide resin, a phenol resin, a cyanate resin, or the like. The core layer 21 may contain, for example, a filler such as silica (SiO₂) or alumina (Al₂O₃). The core layer 21 may have a thickness of, for example, approximately 60 μm to 400 μm.

The core layer 21 includes through holes 21X at given locations (six locations in FIG. 1). The through holes 21X extend through the core layer 21 in the thickness-wise direction. A through-electrode 22 is formed in each through hole 21X and extends through the core layer 21 in the thickness-wise direction. For example, the through hole 21X is filled with the through-electrode 22. The material of the through-electrode 22 may be, for example, copper (Cu) or a copper alloy.

A wiring layer 30, an insulating layer 31, a wiring layer 32, an insulating layer 33, a wiring layer 34, and a solder resist layer 35 are sequentially stacked on a lower surface of the core layer 21. Further, a wiring layer 40, an insulating layer 41, a wiring layer 42, an insulating layer 43, first electrode pads 44, and a solder resist layer 45 are sequentially stacked on an upper surface of the core layer 21. The wiring layers 30, 32, 34, 40, and 42 and the first electrode pads 44 of the first wiring substrate 20 each have a lower wiring density than wiring layers of the second wiring substrate 60. In other words, the wiring layers 30, 32, 34, 40, and 42 and the first electrode pads 44 of the first wiring substrate 20 each have a larger line-and-space (L/S) than the wiring layers of the second wiring substrate 60. The line-and-space (L/S) of the wiring layers 30, 32, 34, 40, and 42 and the first electrode pads 44 may each be, for example, approximately 20 μm/20 μm. In line-and-space (L/S), line (L) represents the width of wiring, and space(S) represents the interval between adjacent wiring parts. For example, when “L/S” is indicated as 20 μm/20 μm, the width of wiring is 20 μm, and the interval between adjacent wiring parts is 20 μm.

The material of the wiring layers 30, 32, 34, 40, and 42 and the first electrode pads 44 may be, for example, copper or a copper alloy. The material of the insulating layers 31, 33, 41, and 43 may be, for example, a non-photosensitive insulating resin including a thermosetting resin, such as an epoxy resin or a polyimide resin, as a main component. The insulating layers 31, 33, 41, and 43 may each contain, for example, a filler such as silica or alumina. The material of the solder resist layers 35 and 45 may be, for example, an insulating resin including a photosensitive resin, such as a phenol resin or a polyimide resin, as a main component. The solder resist layers 35 and 45 may each contain, for example, a filler such as silica or alumina.

The wiring layer 30 is formed on the lower surface of the core layer 21. The wiring layer 30 is electrically connected to the wiring layer 40 by the through-electrodes 22. The insulating layer 31 is formed on the lower surface of the core layer 21 and covers the wiring layer 30. The wiring layer 32 is formed on a lower surface of the insulating layer 31. For example, the wiring layer 32 is formed integrally with via wiring extending through the insulating layer 31 in the thickness-wise direction and is electrically connected to the wiring layer 30 by the via wiring. The insulating layer 33 is formed on the lower surface of the insulating layer 31 and covers the wiring layer 32. The wiring layer 34 is formed on a lower surface of the insulating layer 33. The wiring layer 34 is the lowermost wiring layer of the first wiring substrate 20. For example, the wiring layer 34 is formed integrally with via wiring extending through the insulating layer 33 in the thickness-wise direction and is electrically connected to the wiring layer 32 by the via wiring.

The wiring layers 30, 32, and 34 may have a thickness of, for example, approximately 15 μm to 35 μm. The insulating layers 31 and 33 may have a thickness of, for example, approximately 20 μm to 45 μm.

The solder resist layer 35 is the outermost insulating layer (lowermost insulating layer) of the first wiring substrate 20. The solder resist layer 35 is formed on the lower surface of the insulating layer 33 and covers the wiring layer 34. The solder resist layer 35 includes openings 35X that expose parts of the wiring layer 34 as external connection pads 34P. The external connection pads 34P are connectible to external connection terminals used when mounting the stacked wiring substrate 10 on a mounting substrate such as a motherboard.

A surface-processed layer is formed, if necessary, on a lower surface of the wiring layer 34 exposed at the bottom of each opening 35X. Examples of the surface-processed layer include a gold (Au) layer, a nickel (Ni) layer/Au layer (metal layer in which Ni layer serves as bottom layer, and Au layer is formed on Ni layer), an Ni layer/palladium (Pd) layer/Au layer (metal layer in which Ni layer serves as bottom layer, and Pd layer and Au layer are sequentially formed on Ni layer), or the like. Further examples of the surface-processed layer include an Ni layer/Pd layer (metal layer in which Ni layer serves as bottom layer, and Pd layer is formed on Ni layer), a Pd layer/Au layer (metal layer in which Pd layer serves as bottom layer, and Au layer is formed on Pd layer), or the like. An Au layer is a metal layer formed from Au or an Au alloy, an Ni layer is a metal layer formed from Ni or an Ni alloy, and a Pd layer is a metal layer formed from Pd or a Pd alloy. An Au layer, an Ni layer, and a Pd layer may each be, for example, a metal layer formed by an electroless plating process (electroless plating metal layer) or a metal layer formed by an electrolytic plating process (electrolytic plating metal layer). Alternatively, the surface-processed layer may be an organic solderability preservative (OPS) film formed by performing an anti-oxidation process, such as an OSP process, on the lower surface of the wiring layer 34 exposed from each opening 35X. The OSP film may be an organic coating of an azole compound, an imidazole compound, or the like. When a surface-processed layer is formed on the lower surface of the wiring layer 34, the surface-processed layer acts as the external connection pad 34P. The wiring layer 34 exposed from the opening 35X (or surface-processed layer, if surface-processed layer is formed on wiring layer 34) may be used as an external connection terminal.

The external connection pad 34P and the opening 35X may have any shape and any size in plan view. The planar shapes of the external connection pad 34P and the opening 35X may each be, for example, circular and have a diameter of approximately 200 μm to 300 μm.

The wiring layer 40 is formed on the upper surface of the core layer 21. The wiring layer 40 is electrically connected to the wiring layer 30 by the through-electrodes 22. The insulating layer 41 is formed on the upper surface of the core layer 21 and covers the wiring layer 40. The insulating layer 41 includes through holes 41X extending through the insulating layer 41 in the thickness-wise direction and exposing parts of an upper surface of the wiring layer 40. The wiring layer 42 is formed on an upper surface of the insulating layer 41. For example, the wiring layer 42 is formed integrally with via wiring 42V arranged in each through hole 41X and is electrically connected to the wiring layer 40 by the via wiring 42V. For example, the through hole 41X is filled with the via wiring 42V.

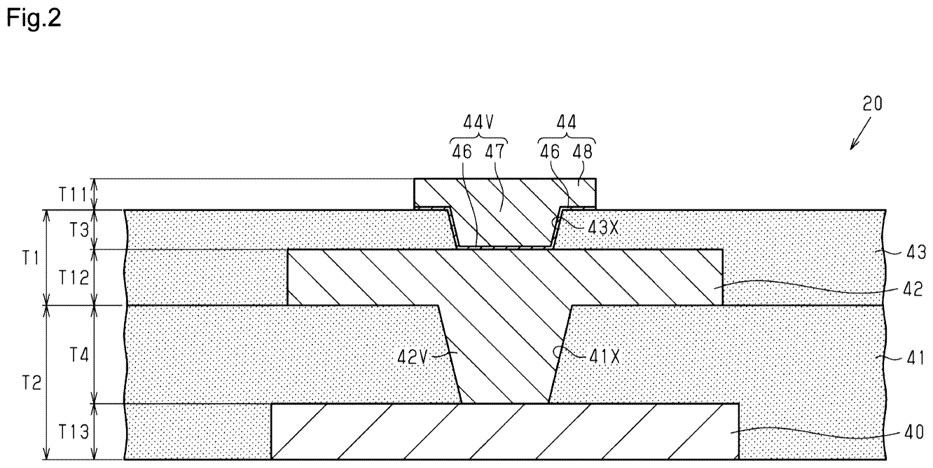

As illustrated in FIG. 2, the insulating layer 43 is formed on the upper surface of the insulating layer 41 and covers the wiring layer 42. The insulating layer 43 is the outermost (uppermost, in FIG. 2) interlayer insulating layer of the first wiring substrate 20. The insulating layer 43 is, for example, the outermost build-up resin layer. The insulating layer 43 includes through holes 43X extending through the insulating layer 43 in the thickness-wise direction and exposing parts of an upper surface of the wiring layer 42.

The insulating layer 43 has a thickness T1 that is less than a thickness T2 of the insulating layer 41. The thickness T1 of the insulating layer 43 is, for example, 0.3 to 0.8 times the thickness T2 of the insulating layer 41. The thickness T1 of the insulating layer 43 may be, for example, approximately 20 μm to 30 μm. The thickness T2 of the insulating layer 41 may be, for example, approximately 40 μm to 50 μm.

The first electrode pad 44 is formed on an upper surface of the insulating layer 43. The first electrode pad 44 is the uppermost wiring layer of the first wiring substrate 20. The first electrode pad 44 acts as an external connection terminal for electrical connection to the second wiring substrate 60 (refer to FIG. 1). For example, the first electrode pad 44 is formed integrally with via wiring 44V extending through the insulating layer 43 in the thickness-wise direction and is electrically connected to the wiring layer 42 by the via wiring 44V.

The first electrode pad 44 and the via wiring 44V include, for example, a seed layer 46 that covers the upper surface of the insulating layer 43 and a wall surface of the through hole 43X. For example, the seed layer 46 continuously covers the upper surface of the insulating layer 43, the entire wall surface of the through hole 43X, and the entire upper surface of the wiring layer 42 exposed from the bottom of the through hole 43X. The material of the seed layer 46 may be, for example, copper or a copper alloy. The seed layer 46 may be, for example, an electroless plating layer formed by an electroless plating process or a sputtered film formed by a sputtering process.

The via wiring 44V includes a metal layer 47 that is formed on the seed layer 46 and fills the through hole 43X. The material of the metal layer 47 may be, for example, copper or a copper alloy. The metal layer 47 may be, for example, an electrolytic plating layer formed by an electrolytic plating process.

The seed layer 46 and the metal layer 47 in the through hole 43X form the via wiring 44V.

The via wiring 44V has a thickness T3 that is less than a thickness T4 of the via wiring 42V. The thickness T3 of the via wiring 44V is the thickness from the upper surface of the wiring layer 42 to the upper surface of the insulating layer 43. The thickness T4 of the via wiring 42V is the thickness from the upper surface of the wiring layer 40 to the upper surface of the insulating layer 41. The thickness T3 of the via wiring 44V may be, for example, approximately 10 μm to 20 μm. The thickness T4 of the via wiring 42V may be, for example, approximately 25 μm to 35 μm.

The via wiring 44V may have any shape and any size in plan view. The planar shape of the via wiring 44V is, for example, circular. In plan view, the via wiring 44V has a smaller size than the via wiring 42V. The via wiring 44V has, for example, a smaller diameter than the via wiring 42V. The diameter of an upper end surface of the via wiring 44V may be, for example, approximately 25 μm to 45 μm. The diameter of an upper end surface of the via wiring 42V may be, for example, approximately 55 μm to 75 μm.

The first electrode pad 44 includes a metal layer 48. The metal layer 48 is formed over the seed layer 46, which is formed on the upper surface of the insulating layer 43, and the via wiring 44V (metal layer 47). The metal layer 48 projects upward from the upper surface of the insulating layer 43. The metal layer 48 is, for example, formed integrally with the metal layer 47. The material of the metal layer 48 may be, for example, copper or a copper alloy. The metal layer 48 may be, for example, an electrolytic plating layer formed by an electrolytic plating process.

The metal layer 48 and the seed layer 46, which is formed on the upper surface of the insulating layer 43, form the first electrode pad 44.

The first electrode pad 44 has a thickness T11 that is, for example, less than a thickness T12 of the wiring layer 42. The thickness T11 of the first electrode pad 44 is, for example, less than a thickness T13 of the wiring layer 40. The thickness T11 of the first electrode pad 44 may be, for example, approximately 5 μm to 10 μm. The thickness T12 of the wiring layer 42 and the thickness T13 of the wiring layer 40 may each be, for example, approximately 10 μm to 20 μm. The thickness T4 of the via wiring 42V may be greater than the thickness T13 of the wiring layer 40, whereas the thickness T3 of the via wiring 44V may be equal to or less than the thickness T12 of the wiring layer 42.

The first electrode pad 44 may have any shape and any size in plan view. The planar shape of the first electrode pads 44 is, for example, circular. The diameter of the first electrode pad 44 may be, for example, approximately 70 μm to 85 μm.

As illustrated in FIG. 1, the solder resist layer 45 is the outermost insulating layer (uppermost insulating layer) of the first wiring substrate 20. The solder resist layer 45 is formed on the upper surface of the insulating layer 43. The solder resist layer 45 is formed on the upper surface of the insulating layer 43 and exposes the first electrode pads 44. The solder resist layer 45 includes an open portion 45X extending through the solder resist layer 45 in the thickness-wise direction and exposing the first electrode pads 44 and part of the upper surface of the insulating layer 43. In plan view, the open portion 45X overlaps, for example, a mounting region in which the second wiring substrate 60 is mounted. The open portion 45X exposes the first electrode pads 44 and part of the upper surface of the insulating layer 43 that are located in the mounting region. In other words, the solder resist layer 45 surrounds the mounting region in plan view.

The first wiring substrate 20 may have any shape and any size in plan view. In plan view, the first wiring substrate 20 has a larger size than the second wiring substrate 60. The planar shape of the first wiring substrate 20 may be, for example, quadrangular and have a size of approximately 60 mm×60 mm to 80 mm×80 mm.

### Structure of Second Wiring Substrate 60

The second wiring substrate 60 includes second electrode pads 70, an insulating layer 71, an insulating layer 72, a wiring layer 73, and a wiring structure 61. The wiring structure 61 is arranged on the insulating layer 72 and the wiring layer 73. The wiring structure 61 is a fine wiring structure that includes wiring layers having a higher wiring density than the first wiring substrate 20. The wiring structure 61 includes a wiring layer 74, an insulating layer 75, a wiring layer 76, an insulating layer 77, a wiring layer 78, an insulating layer 79, and a wiring layer 80. The material of the second electrode pads 70 and the wiring layers 73, 74, 76, 78, and 80 may be, for example, copper or a copper alloy.

The second wiring substrate 60 may have any shape and size in plan view. The planar shape of the second wiring substrate 60 may be, for example, quadrangular and have a size of 30 mm×30 mm to 50 mm×50 mm.

The second electrode pads 70 are the lowermost wiring layer of the second wiring substrate 60. The second electrode pads 70 are covered by the insulating layer 71. A lower surface of each second electrode pad 70 is exposed from a lower surface of the insulating layer 71. The lower surface of the second electrode pad 70 is, for example, flush with the lower surface of the insulating layer 71. The second electrode pad 70 acts as an external connection terminal for electrical connection to another wiring substrate, that is, the first wiring substrate 20. The second electrode pad 70 may have a thickness of, for example, approximately 10 μm to 20 μm.

The second electrode pad 70 may have any shape and any size in plan view. In plan view, the second electrode pad 70 has, for example, a larger size than the first electrode pad 44. The planar shape of the second electrode pad 70 is, for example, circular. The diameter of the second electrode pad 70 may be, for example, approximately 90 μm to 110 μm.

The insulating layer 71 covers upper and side surfaces of each second electrode pad 70 and exposes the lower surface of the second electrode pad 70. The insulating layer 71 is an insulating layer that includes a non-photosensitive thermosetting resin as a main component, and does not include a reinforcement member. Examples of the thermosetting resin include an epoxy resin, an imide resin, a phenolic resin, a cyanate resin, or the like. The insulating layer 71 may contain a filler such as silica or alumina. The insulating layer 71 may have a thickness of, for example, approximately 15 μm to 30 μm.

The insulating layer 72 is an insulating layer that includes a non-photosensitive thermosetting resin as a main component. The insulating layer 72 further includes a reinforcement member 72G. The insulating layer 72 has a higher rigidity than the insulating layer 71. The insulating layer 72 may be formed by impregnating the reinforcement member 72G with a non-photosensitive thermosetting resin. Examples of the thermosetting resin include an epoxy resin, an imide resin, a phenolic resin, a cyanate resin, or the like. The reinforcement member 72G may be, for example, a non-woven fabric or a woven fabric, such as glass fiber, a carbon fiber, or an aramid fiber. The insulating layer 72 may have a thickness of, for example, approximately 30 μm to 50 μm.

The wiring layer 73 is via wiring embedded in the insulating layers 71 and 72. In the example illustrated in FIG. 1, the wiring layer 73 is the via wiring that fills through holes 72X. The through holes 72X extend through the insulating layers 71 and 72 in the thickness-wise direction and expose parts of the upper surface of the second electrode pads 70. The wiring layer 73 is electrically connected to the second electrode pads 70. The wiring layer 73 is tapered such that its diameter decreases from the upper side (side close to wiring layer 74) toward the lower side (side close to second electrode pad 70) in FIG. 1. The wiring layer 73 has the form of, for example, a reversed truncated cone so that its upper end surface has a larger diameter than its lower end surface. The upper end surface of the wiring layer 73 is exposed from the insulating layer 72. The upper end surface of the wiring layer 73 is, for example, flush with an upper surface of the insulating layer 72. The upper end surface of the wiring layer 73 is directly bonded to a lower surface of the wiring layer 74. The lower end surface of the wiring layer 73 is directly bonded to the upper surface of the second electrode pads 70. The diameter of the upper end surface of the wiring layer 73 may be, for example, approximately 60 μm to 70 μm.

### Wiring Structure 61

The wiring layer 74 is formed on the upper surface of the insulating layer 72 and is connected to the upper end surface of the wiring layer 73. Part of the lower surface of the wiring layer 74 is in contact with the upper end surface of the wiring layer 73 so that the wiring layer 74 is electrically connected to the wiring layer 73. In other words, although the wiring layer 74 is electrically connected to the wiring layer 73, the wiring layer 74 and the wiring layer 73 are not integrated with each other. The wiring layer 74 includes, for example, a seed layer formed on the upper end surface of the wiring layer 73 and a metal layer formed on the seed layer.

The insulating layer 75 is formed on the upper surface of the insulating layer 72 and covers the wiring layer 74. The wiring layer 76 is formed on an upper surface of the insulating layer 75. For example, the wiring layer 76 is formed integrally with via wiring extending through the insulating layer 75 in the thickness-wise direction and is electrically connected to the wiring layer 74 by the via wiring. The insulating layer 77 is formed on the upper surface of the insulating layer 75 and covers the wiring layer 76. The wiring layer 78 is formed on an upper surface of the insulating layer 77. The wiring layer 78 is formed integrally with via wiring extending through the insulating layer 77 in the thickness-wise direction and is electrically connected to the wiring layer 76 by the via wiring. The insulating layer 79 is formed on the upper surface of the insulating layer 77 and covers the wiring layer 78.

The wiring layer 80 is formed on an upper surface of the insulating layer 79. The wiring layer 80 is the uppermost wiring layer of the second wiring substrate 60. For example, the wiring layer 80 is formed integrally with via wiring extending through the insulating layer 79 in the thickness-wise direction and is electrically connected to the wiring layer 78 by the via wiring. The wiring layer 80 includes pads P1. The pads P1 act as electronic component mounting pads for electrical connection to an electronic component such as a semiconductor chip. The pads P1 may have any shape and any size in plan view. The planar shape of each pad P1 may be, for example, circular and have a diameter of approximately 20 μm to 30 μm. The distance between consecutive pads P1 may be, for example, approximately 40 μm to 60 μm. The pad P1 may have a thickness of, for example, approximately 10 μm to 15 μm.

A surface-processed layer is formed, if necessary, on the surfaces (upper and side surfaces or upper surface only) of the pads P1. Examples of the surface-processed layer include an OSP film or a metal layer, such as an Au layer, an Ni layer/Au layer, an Ni layer/Pd layer/Au layer, an Ni layer/Pd layer, or a Pd layer/Au layer.

Each of the wiring layers 74, 76, 78, and 80 of the wiring structure 61 is thinner than the second electrode pad 70. Each of the wiring layers 74, 76, 78, and 80 is thinner than each of the wiring layers 30, 32, 34, 40, and 42 and the first electrode pad 44 of the first wiring substrate 20. The wiring layers 74, 76, and 78 may each have a thickness of, for example, approximately 1 μm to 3 μm. The wiring layer 80 may have a thickness of, for example, approximately 5 μm to 15 μm. Each of the wiring layers 74, 76, 78, and 80 has a higher wiring density than the second electrode pad 70. In other words, each of the wiring layers 74, 76, 78, and 80 has a smaller line-and-space than the second electrode pad 70. Each of the wiring layers 74, 76, 78, and 80 has a higher wiring density than each of the wiring layers 30, 32, 34, 40, and 42 and the first electrode pad 44 of the first wiring substrate 20. The line-and-space (L/S) of the wiring layers 74, 76, 78, and 80 may each be approximately 1 μm/1 μm to 3 μm/3 μm.

The material of the insulating layers 75, 77, and 79 of the wiring structure 61 may be, for example, a photosensitive insulating resin including a phenol resin, a polyimide resin, or the like, as a main component. The insulating layers 75, 77, and 79 may each contain, for example, a filler such as silica or alumina. Each of the insulating layers 75, 77, and 79 is thinner than each of the insulating layers 31, 33, 41, and 43 of the first wiring substrate 20. The insulating layers 75, 77, and 79 may each have a thickness of, for example, approximately 5 μm to 10 μm.

The second wiring substrate 60 is mounted on the first wiring substrate 20. The second wiring substrate 60 is, for example, mounted on the first electrode pads 44 of the first wiring substrate 20. For example, a solder layer 81 joins the first electrode pads 44 of the first wiring substrate 20 to the second electrode pads 70 of the second wiring substrate 60. The solder layer 81 is, for example, joined to upper and side surfaces of each first electrode pad 44 and the lower surface of each second electrode pad 70. The material of the solder layer 81 may be, for example, an alloy containing lead (Pb), an alloy of tin (Sn) and Au, an alloy of Sn and Cu, an alloy of Sn and silver (Ag), an alloy of Sn, Ag, and Cu, or the like.

The underfill resin 85 fills the gap between the first wiring substrate 20 and the second wiring substrate 60. The underfill resin 85 fills the gap between the upper surface of the insulating layer 43 exposed from the open portion 45X and the lower surface of the insulating layer 71 of the second wiring substrate 60. The material of the underfill resin 85 may be, for example, an insulating resin such as epoxy resin.

In this manner, the second wiring substrate 60, which includes the wiring layers having a relatively high wiring density, is mounted on the first wiring substrate 20, which includes the wiring layers having a relatively low wiring density. This facilitates the manufacture of the stacked wiring substrate 10 on which electronic components such as semiconductor chips are mounted.

In the stacked wiring substrate 10 of the first embodiment, the wiring layer 40 is an example of a first wiring layer, the insulating layer 41 is an example of a first insulating layer, the wiring layer 42 is an example of a second wiring layer, and the insulating layer 43 is an example of a second insulating layer. The through hole 43X is an example of a first through hole, and the through hole 41X is an example of a second through hole. The via wiring 44V is an example of first via wiring, and the via wiring 42V is an example of second via wiring.

### Structure of Semiconductor Device 90

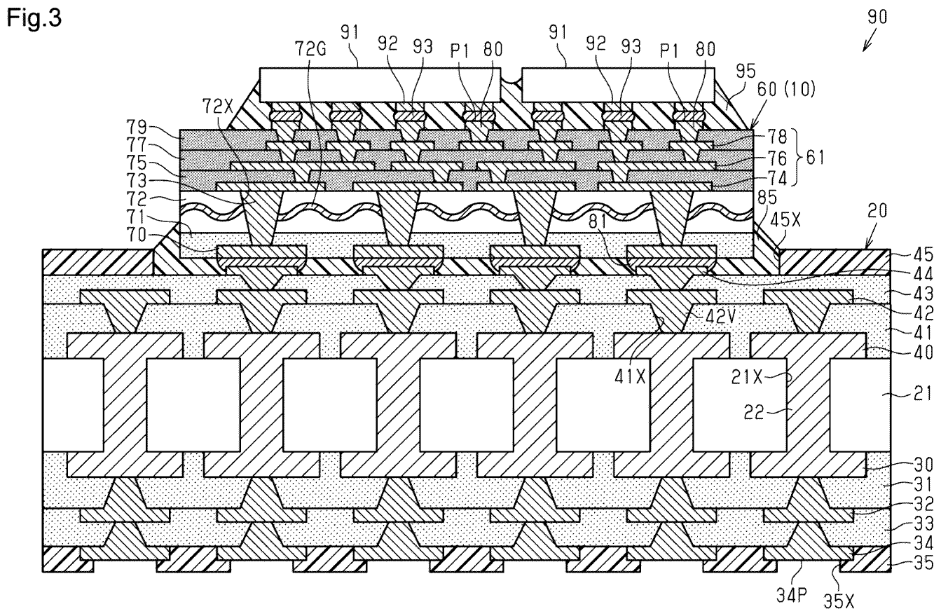

The structure of a semiconductor device 90 will now be described with reference to FIG. 3.

The semiconductor device 90 includes the stacked wiring substrate 10, one or more (two, in the present embodiment) semiconductor chips 91, and an underfill resin 95.

Each of the semiconductor chips 91 includes, for example, electrode pads 92 formed on a circuit formation surface (lower surface) of the semiconductor chip 91. The semiconductor chip 91 is flip-chip-mounted on the second wiring substrate 60. The electrode pads 92 of the semiconductor chip 91 are, for example, electrically connected to the pads P1 of the second wiring substrate 60 by bumps 93. In this manner, the semiconductor chips 91 are electrically connected to the wiring layer 80 by the electrode pads 92 and the bumps 93.

The semiconductor chips 91 may each be, for example, a logic chip such as a central processing unit (CPU) chip or a graphics processing unit (GPU) chip. Alternatively, the semiconductor chips 91 may each be, for example, a memory chip such as a dynamic random access memory (DRAM) chip, a static random access memory (SRAM) chip, or a flash memory chip. Semiconductor chips including combinations of the logic chips and the memory chips may be mounted on the second wiring substrate 60. The semiconductor chips 91 may have the same size or different sizes.

The bumps 93 may be, for example, gold bumps or solder bumps. The material of solder bumps may be, for example, an alloy containing Pb, an alloy of Sn and Au, an alloy of Sn and Cu, an alloy of Sn and Ag, an alloy of Sn, Ag, and Cu, or the like.

The gap between the second wiring substrate 60 and the semiconductor chip 91 is filled with the underfill resin 95. The material of the underfill resin 95 may be, for example, an insulating resin such as an epoxy resin.

In the semiconductor device 90, the semiconductor chips 91 are mounted on the second wiring substrate 60, which includes the wiring layers having a relatively high wiring density. This allows the semiconductor chips 91 to be readily signal-connected to each other by the wiring layers having a relatively high wiring density.

### Method for Manufacturing Stacked Wiring Substrate 10

A method for manufacturing the stacked wiring substrate 10 will now be described. To facilitate understanding, portions that will become final elements of the stacked wiring substrate 10 are given the same reference characters as the final elements.

First, a method for manufacturing the first wiring substrate 20 will be described.

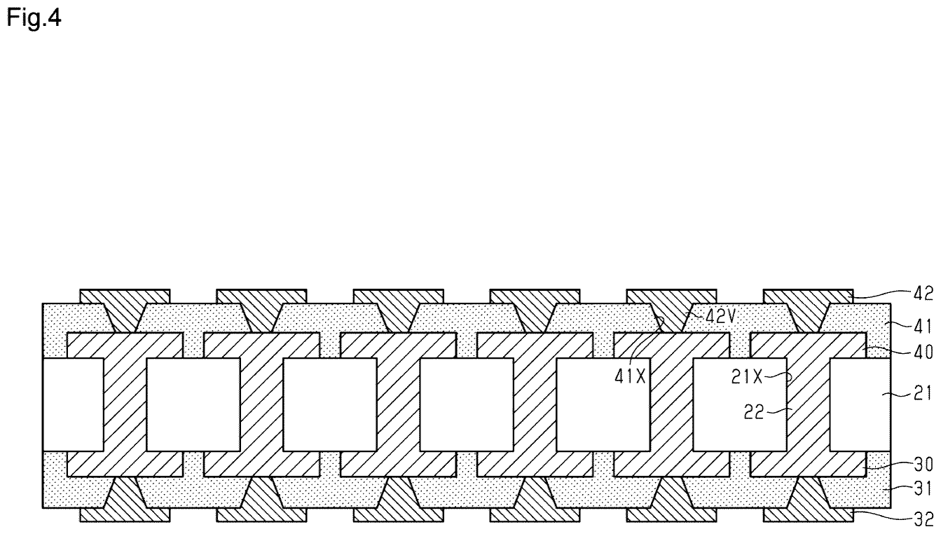

In the step illustrated in FIG. 4, a structural body is prepared by sequentially stacking the wiring layer 30, the insulating layer 31, and the wiring layer 32 on the lower surface of the core layer 21, and the wiring layer 40, the insulating layer 41, and the wiring layer 42 on the upper surface of the core layer 21. Such a structural body may be manufactured by a known manufacturing process, such as a build-up process. Thus, the process will not be described in detail.

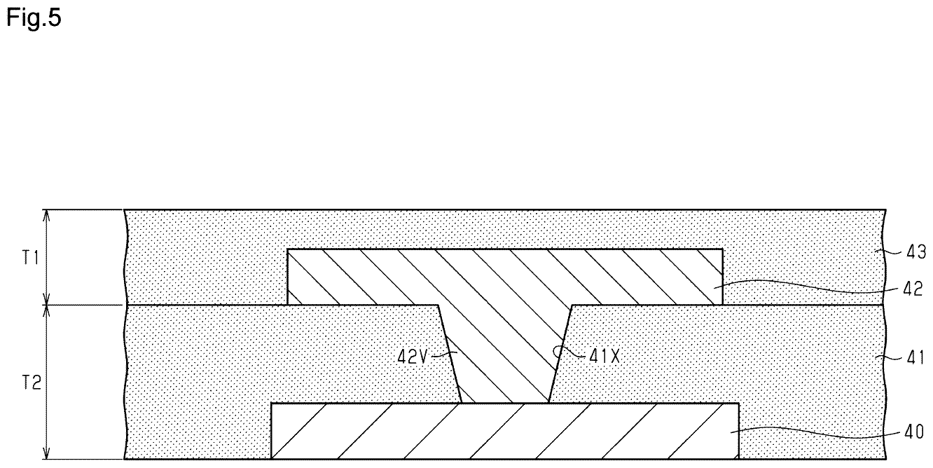

In the step illustrated in FIG. 5, the insulating layer 43 is formed on the upper surface of the insulating layer 41 and covers the wiring layer 42. For example, the upper surface of the insulating layer 41 is laminated with a multilayer film, in which insulating resin films are stacked in a semi-cured state, so that the wiring layer 42 is covered. Then, pressure and heat are applied to the multilayer film so as to cure the multilayer film and form the insulating layer 43. The insulating layer 43 is formed such that the thickness T1 of the insulating layer 43 becomes less than the thickness T2 of the insulating layer 41. The thickness T1 of the insulating layer 43 may be adjusted, for example, by changing the number of insulating resin films in the multilayer film. In the present example, the number of insulating resin films is set to one so that the thickness T1 of the insulating layer 43 is less than the thickness T2 of the insulating layer 41. FIGS. 5 to 10 each illustrate part of the structural body that corresponds to the portion illustrated in FIG. 2.

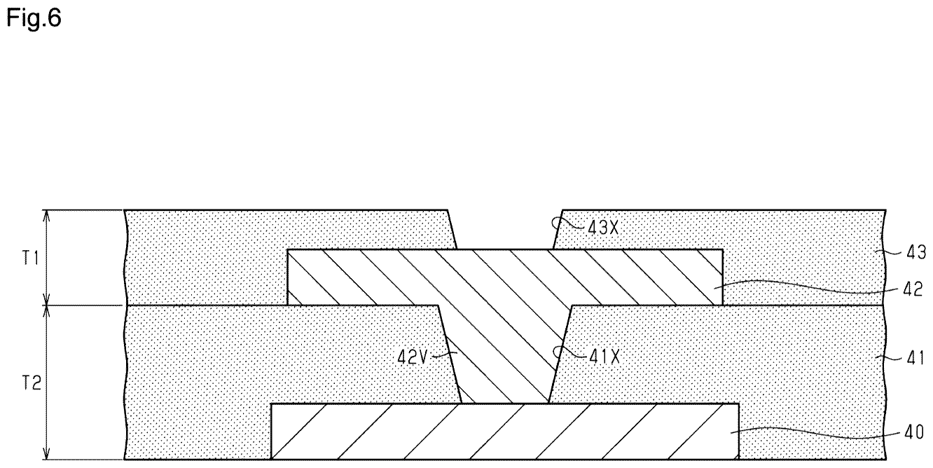

In the step illustrated in FIG. 6, the through holes 43X are formed in the insulating layer 43 and expose parts of the upper surface of the wiring layer 42. The through holes 43X may be formed, for example, by performing laser drilling that uses a CO₂ laser, a UV-YAG laser, or the like. In this case, since the thickness T1 of the insulating layer 43 is set relatively small, the thickness from the upper surface of the wiring layer 42 to the upper surface of the insulating layer 43 is relatively small. This allows the through holes 43X to be reduced in depth and the opening diameter (diameter, in the present example).

When the through holes 43X are formed by laser drilling, a desmear process is then performed to remove resin smears from the surface of the wiring layer 42 exposed at the bottom of each through hole 43X.

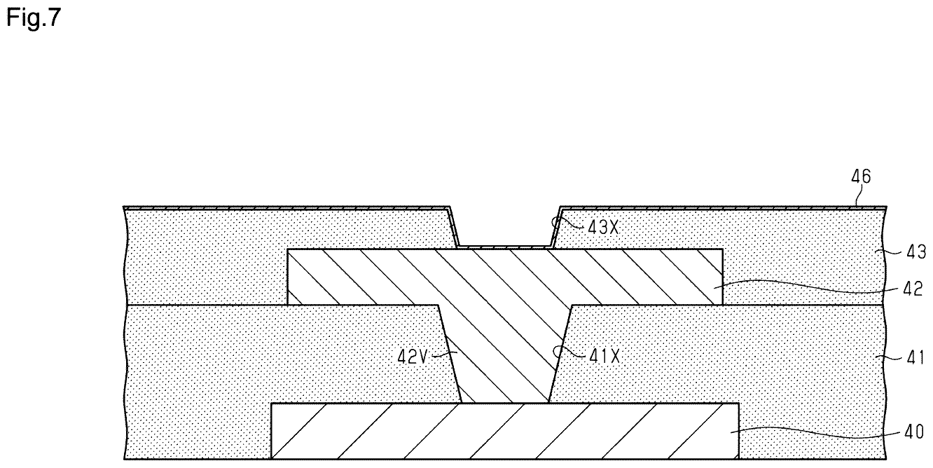

In the step illustrated in FIG. 7, the seed layer 46 is formed to cover the entire upper surface of the insulating layer 43, the entire wall surface of each through hole 43X, and the entire upper surface of the wiring layer 42 exposed from the bottom of each through hole 43X. The seed layer 46 may be formed, for example, by a sputtering process or an electroless plating process. When forming the seed layer 46 by sputtering, for example, titanium (Ti) is first sputtered and deposited on the upper surface of the insulating layer 43 and the wall surface of the through holes 43X so that the upper surface of the insulating layer 43 and the wall surface of the through holes 43X are covered by a Ti layer. Subsequently, copper is sputtered and deposited on the Ti layer to form a Cu layer. This forms the seed layer 46 with a double-layered structure (Ti layer/Cu layer). Alternatively, when forming the seed layer 46 by electroless plating, for example, electroless copper plating may be performed to form the seed layer 46 with a Cu layer (single-layered structure).

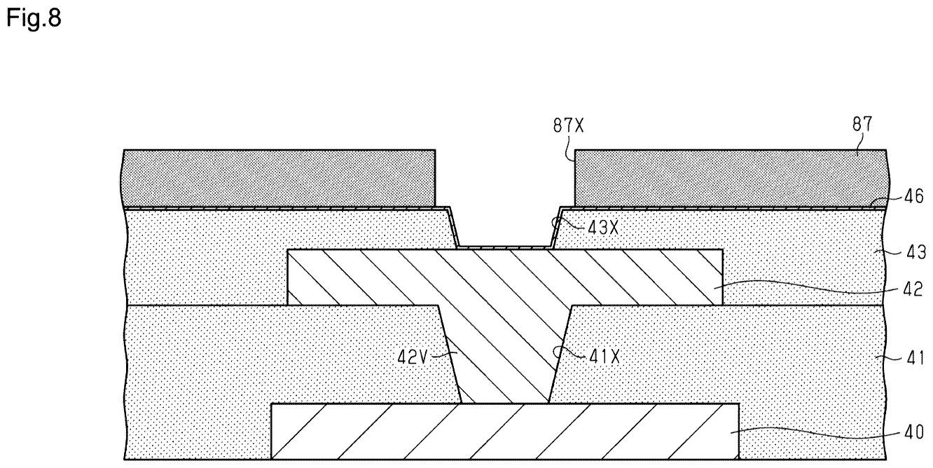

In the step illustrated in FIG. 8, a resist layer 87 including an opening pattern 87X at a given location is formed on the seed layer 46. The opening pattern 87X exposes parts of the seed layer 46 in correspondence with regions where the first electrode pads 44 are formed (refer to FIG. 2). The material of the resist layer 87 may be, for example, a material that is resistant to electrolytic plating performed in a subsequent process. For example, a photosensitive dry film resist or a liquid photoresist may be used as the resist layer 87. Examples of such a resist material include a novolac resin, an acrylic resin, or the like. When using a photosensitive dry film resist, the upper surface of the seed layer 46 is laminated with a dry film through thermocompression bonding, and then the dry film is patterned by photolithography to form the resist layer 87 including the opening pattern 87X. When using a liquid photoresist, the resist layer 87 may be formed by a similar process.

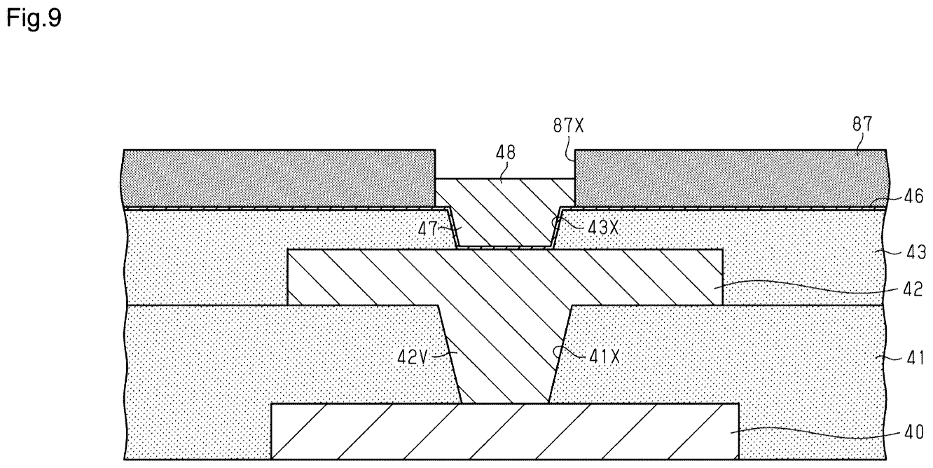

In the step illustrated in FIG. 9, electrolytic plating is performed on the seed layer 46 using the resist layer 87 as a plating mask and the seed layer 46 as a plating power feeding layer. That is, electrolytic plating (electrolytic Cu plating) is performed on the upper surface of the seed layer 46 exposed from the opening pattern 87X of the resist layer 87. The present step forms the metal layer 47 and the metal layer 48. The metal layer 47 is formed on the seed layer 46 and fills the through holes 43X. The metal layer 48 is arranged in the opening pattern 87X.

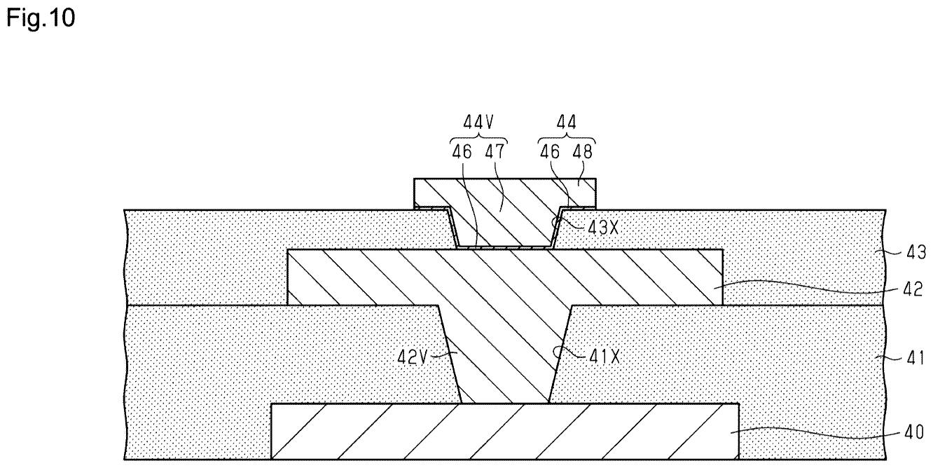

In the step illustrated in FIG. 10, the resist layer 87 in FIG. 9 is removed using an alkali stripping solution (e.g., organic amine stripping solution, caustic soda, acetone, or ethanol).

Subsequently, etching is performed using the metal layer 48 as an etching mask to remove unnecessary portions of the seed layer 46. The present step forms the via wiring 44V and the first electrode pads 44. The via wiring 44V includes the seed layer 46 and the metal layer 47 that are arranged in the through holes 43X. The first electrode pads 44 are formed on the upper surface of the insulating layer 43 and include the seed layer 46 and the metal layer 48.

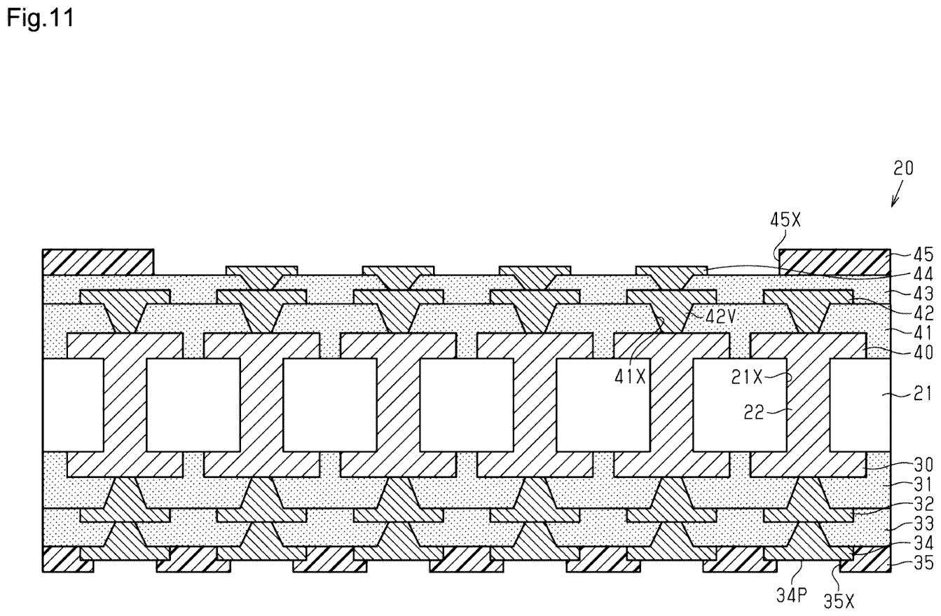

As illustrated in FIG. 11, the insulating layer 33 and the wiring layer 34 are sequentially stacked on the lower surface of the insulating layer 31. The insulating layer 33 and the wiring layer 34 are formed, for example, at the same time as when the insulating layer 43 and the first electrode pads 44 are formed.

In the step illustrated in FIG. 11, the solder resist layer 35 including the openings 35X, which expose parts of the wiring layer 34 as the external connection pads 34P, is formed on the lower surface of the insulating layer 33. Also, the solder resist layer 45 including the open portion 45X, which exposes the mounting region of the second wiring substrate 60 (refer to FIG. 1), is formed on the upper surface of the insulating layer 43. The solder resist layers 35 and 45 may each be formed, for example, by applying a photosensitive solder resist film or a liquid solder resist and patterning the resist into a desired shape. The above-described process manufactures the first wiring substrate 20.

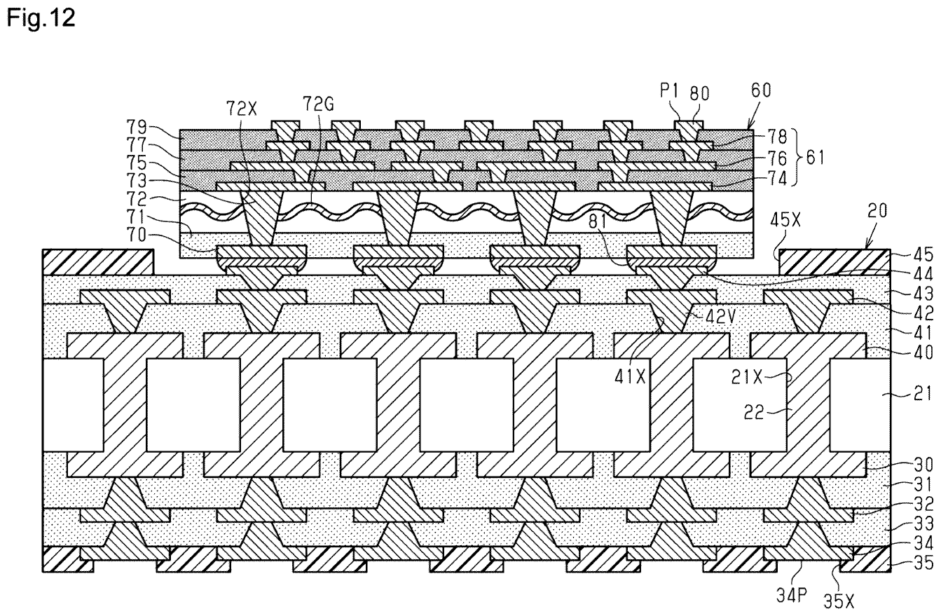

In the step illustrated in FIG. 12, the second wiring substrate 60 is manufactured. The second wiring substrate 60 may be manufactured by a known manufacturing process. Thus, such a process will not be described in detail.

The second wiring substrate 60 is mounted on the first wiring substrate 20. In the present example, the solder layer 81 formed on the lower surface of the second electrode pads 70 of the second wiring substrate 60 is joined to the first electrode pads 44 of the first wiring substrate 20.

Then, the gap between the joined first wiring substrate 20 and second wiring substrate 60 is filled with the underfill resin 85 (refer to FIG. 1), and the underfill resin 85 is cured. The above-described manufacturing process manufactures the stacked wiring substrate 10 illustrated in FIG. 1.

The present embodiment has the following advantages.

(1) In the first wiring substrate 20, the insulating layer 43, which is the uppermost interlayer insulating layer of the first wiring substrate 20, is formed to be thinner than the insulating layer 41, which is another insulating layer of the first wiring substrate 20. Accordingly, the thickness T3 of the via wiring 44V extending through the insulating layer 43 in the thickness-wise direction is less than the thickness T4 of the via wiring 42V extending through the insulating layer 41 in the thickness-wise direction. Therefore, the via wiring 44V has a smaller diameter as compared to when the insulating layer 43 and the insulating layer 41 have the same thickness. This allows for a reduction in the diameter of the first electrode pad 44 that is connected to the via wiring 44V. For example, even if a degree of accuracy in positioning the first electrode pads 44 on the via wiring 44V is limited, the via wiring 44V may be reduced in diameter. This mitigates the limited positioning accuracy of the first electrode pads 44 on the via wiring 44V. In this manner, the diameter of the first electrode pad 44 is optimally reduced in correspondence with the reduction in the diameter of the via wiring 44V. As a result, the distance between the consecutive first electrode pads 44 may be sufficiently decreased.

(2) The decrease in the distance between the consecutive first electrode pads 44 allows for, for example, an increase in the number of vias in a power supply unit. This improves power supply performance.

(3) The decrease in the distance between consecutive first electrode pads 44 allows for, for example, an increase in the number of signals that may be extracted from the second wiring substrate 60 to the first wiring substrate 20. This enhances the bandwidth for signal transmission.

(4) In plan view, the first electrode pad 44 has a smaller size than the second electrode pad 70 of the second wiring substrate 60. Thus, when bonding the first electrode pads 44 and the second electrode pads 70 with the solder layer 81, the solder layer 81 formed on the lower surface of the second electrode pads 70 may be bonded to the upper and side surfaces of the first electrode pads 44. This increases the contact area between the first electrode pads 44 and the solder layer 81, thereby improving the bonding strength between the first electrode pads 44 and the solder layer 81, as compared to when the solder layer 81 is bonded to only the upper surface of the first electrode pads 44. Consequently, the connection reliability between the first electrode pads 44 and the second electrode pads 70 is improved.

### Second Embodiment

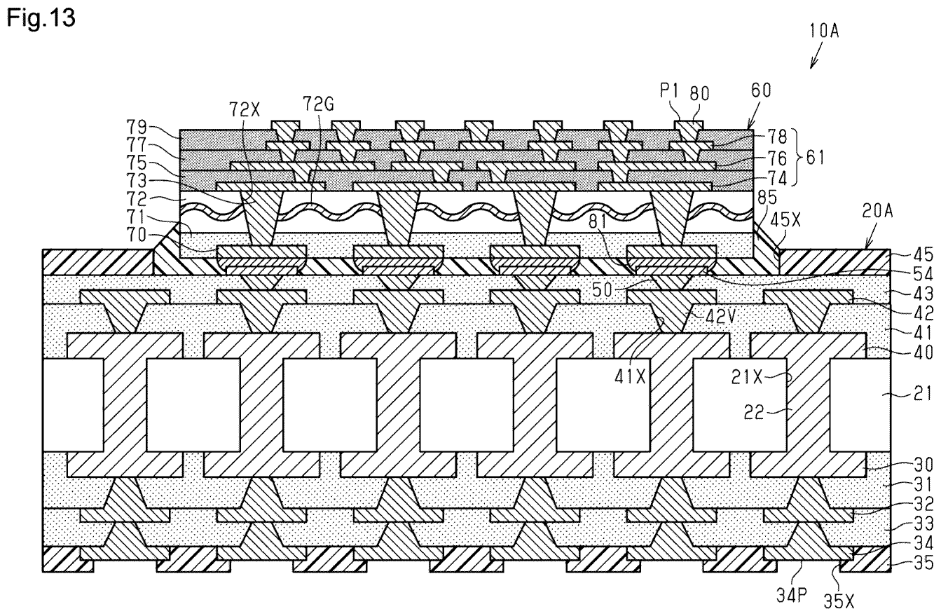

A second embodiment will now be described with reference to FIGS. 13 to 20. In a stacked wiring substrate 10A of the present embodiment, the structure of a first wiring substrate 20A differs from the first embodiment. Hereafter, differences from the first embodiment will be mainly described.

As illustrated in FIG. 13, the stacked wiring substrate 10A includes the first wiring substrate 20A and the second wiring substrate 60 mounted on the first wiring substrate 20A. The stacked wiring substrate 10A includes, for example, the underfill resin 85 formed in a gap between the first wiring substrate 20A and the second wiring substrate 60.

### Structure of First Wiring Substrate 20A

The first wiring substrate 20A includes via wiring 50 and first electrode pads 54. The via wiring 50 extends through the insulating layer 43 in a thickness-wise direction and includes an upper end surface exposed from the insulating layer 43. The first electrode pads 54 are each formed on the upper surface of the insulating layer 43 and the upper end surface of the via wiring 50.

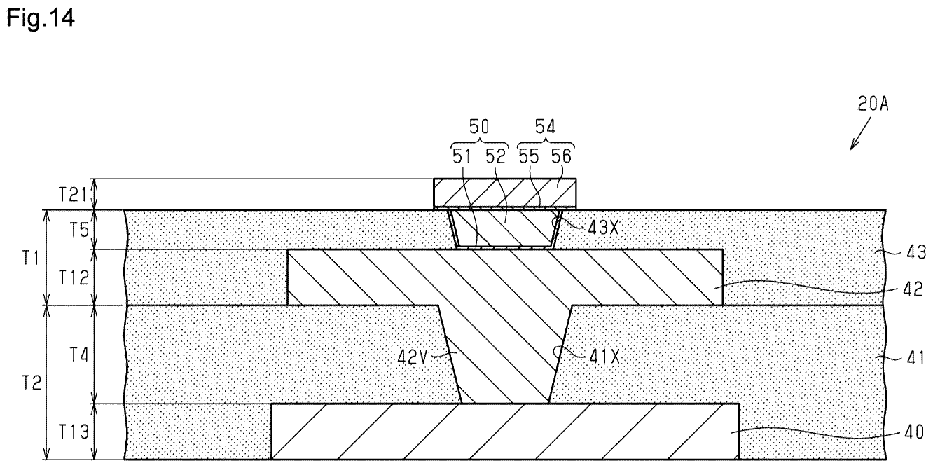

As illustrated in FIG. 14, the via wiring 50 is embedded in the insulating layer 43. The via wiring 50 fills the through hole 43X extending through the insulating layer 43 in the thickness-wise direction and exposing part of the upper surface of the wiring layer 42. The via wiring 50 is electrically connected to the wiring layer 42 and the first electrode pad 54. The via wiring 50 is tapered such that its diameter decreases from the upper side (side close to first electrode pad 54) toward the lower side (side close to wiring layer 42) in FIG. 14. The via wiring 50 has the form of, for example, a reversed truncated cone so that its upper end surface has a larger diameter than its lower end surface. The upper end surface of the via wiring 50 is exposed from the insulating layer 43. The upper end surface of the via wiring 50 is, for example, flush with the upper surface of the insulating layer 43. The upper end surface of the via wiring 50 and the upper surface of the insulating layer 43 are, for example, polished surfaces. The upper end surface of the via wiring 50 is directly bonded to a lower surface of the first electrode pad 54. The lower end surface of the via wiring 50 is directly bonded to the upper surface of the wiring layer 42.

The via wiring 50 includes, for example, a seed layer 51 and a metal layer 52. The seed layer 51 covers an entire wall surface of the through hole 43X. The metal layer 52 is formed on the seed layer 51 and fills the through hole 43X. For example, the seed layer 51 continuously covers the entire wall surface of the through hole 43X and the entire upper surface of the wiring layer 42 exposed from the bottom of the through hole 43X. The material of the seed layer 51 may be, for example, copper or a copper alloy. The seed layer 51 may be, for example, an electroless plating layer formed by an electroless plating process or a sputtered film formed by a sputtering process. An upper end surface of the metal layer 52 is flush with the upper surface of the insulating layer 43. The material of the metal layer 52 may be, for example, copper or a copper alloy. The metal layer 52 may be, for example, an electrolytic plating layer formed by an electrolytic plating process.

The via wiring 50 has a thickness T5 that is less than the thickness T4 of the via wiring 42V. The thickness T5 of the via wiring 50 may be, for example, approximately 5 μm to 15 μm. The via wiring 50 may have any shape and size in plan view. The planar shape of the via wiring 50 is, for example, circular. In plan view, the via wiring 50 has a smaller size than the via wiring 42V. The diameter of the via wiring 50 is, for example, less than the diameter of the via wiring 42V. The diameter of the upper end surface of the via wiring 50 may be, for example, approximately 15 μm to 45 μm. The diameter of the upper surface of the via wiring 42V may be, for example, approximately 55 μm to 75 μm.

The first electrode pad 54 is formed on the upper surface of the insulating layer 43 and is connected to the upper end surface of the via wiring 50. Part of the lower surface of the first electrode pad 54 is in contact with the upper end surface of the via wiring 50 so that the first electrode pad 54 is electrically connected to the via wiring 50. In other words, although the first electrode pad 54 is electrically connected to the via wiring 50, the first electrode pad 54 and the via wiring 50 are not integrated with each other.

The first electrode pad 54 includes a seed layer 55 and a metal layer 56. The seed layer 55 covers the upper surface of the insulating layer 43 and the upper end surface of the via wiring 50. The metal layer 56 is formed on the seed layer 55. That is, the metal layer 56 is connected to the via wiring 50 by the seed layer 55.

The material of the seed layer 55 may be, for example, copper or a copper alloy. The seed layer 55 may be, for example, an electroless plating layer formed by an electroless plating process or a sputtered film formed by a sputtering process. The metal layer 56 covers the entire upper surface of the seed layer 55. The material of the metal layer 56 may be, for example, copper or a copper alloy. The metal layer 56 may be, for example, an electrolytic plating layer formed by an electrolytic plating process.

The first electrode pad 54 has a thickness T21 that is, for example, less than the thickness T12 of the wiring layer 42. The thickness T21 of the first electrode pad 54 is, for example, less than the thickness T13 of the wiring layer 40. The thickness T21 of the first electrode pad 54 may be, for example, approximately 5 μm to 10 μm. The thickness T12 of the wiring layer 42 and the thickness T13 of the wiring layer 40 may each be, for example, approximately 10 μm to 20 μm. The thickness T4 of the via wiring 42V may be greater than the thickness T13 of the wiring layer 40, whereas the thickness T5 of the via wiring 50 may be equal to or less than the thickness T12 of the wiring layer 42.

The first electrode pad 54 may have any shape and any size in plan view. The planar shape of the first electrode pad 54 is, for example, circular. In plan view, the first electrode pad 54 has a smaller size than the second electrode pad 70. The diameter of the first electrode pad 54 may be, for example, approximately 60 μm to 85 μm. The diameter of the second electrode pad 70 may be, for example, approximately 90 μm to 110 μm.

As illustrated in FIG. 13, the second wiring substrate 60 is mounted on the first electrode pads 54 of the first wiring substrate 20A. For example, the solder layer 81 joins the first electrode pads 54 of the first wiring substrate 20A to the second electrode pads 70 of the second wiring substrate 60.

In the stacked wiring substrate 10A of the second embodiment, the wiring layer 40 is an example of a first wiring layer, the insulating layer 41 is an example of a first insulating layer, the wiring layer 42 is an example of a second wiring layer, and the insulating layer 43 is an example of a second insulating layer. The through hole 43X is an example of a first through hole, and the through hole 41X is an example of a second through hole. The via wiring 42V is an example of second via wiring, and the via wiring 50 is an example of third via wiring. The seed layer 51 is an example of a first seed layer, and the seed layer 55 is an example of a second seed layer. The metal layer 52 is an example of a first metal layer, and the metal layer 56 is an example of a second metal layer.

### Method for Manufacturing Stacked Wiring Substrate 10A

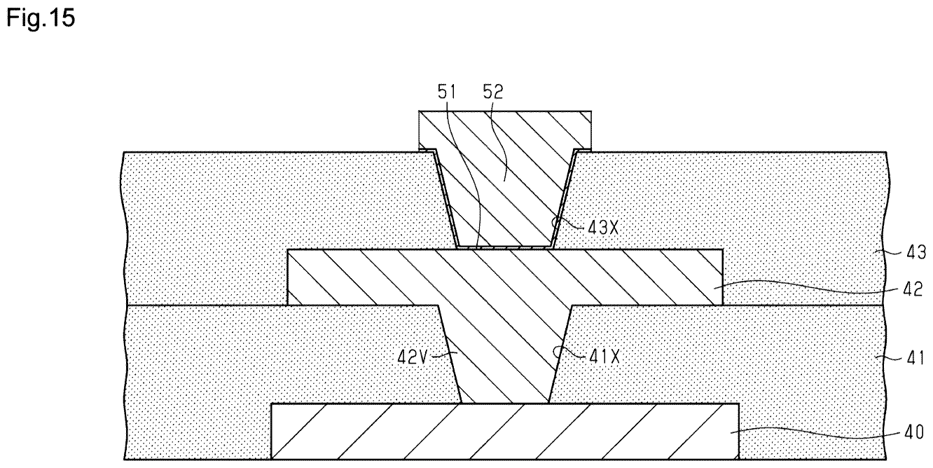

A method for manufacturing the stacked wiring substrate 10A will now be described. In particular, a method for manufacturing the via wiring 50 and the first electrode pads 54 of the first wiring substrate 20A will be described. FIGS. 15 to 20 each illustrate part of the structural body that corresponds to the portion illustrated in FIG. 14. To facilitate understanding, portions that will become final elements of the stacked wiring substrate 10A are given the same reference characters as the final elements.

In the step illustrated in FIG. 15, the same steps of FIGS. 4 to 10 are performed so that the metal layer 52 is formed. The metal layer 52 fills the through hole 43X in the insulating layer 43 and covers the upper surface of the insulating layer 43. The metal layer 52 may cover, for example, the entire upper surface of the insulating layer 43 or cover the upper surface of the insulating layer 43 only in the vicinity of the through hole 43X. In the present step, the insulating layer 43 may have a thickness that is, for example, similar to that of the insulating layer 41. Alternatively, the insulating layer 43 may be thinner than the insulating layer 41.

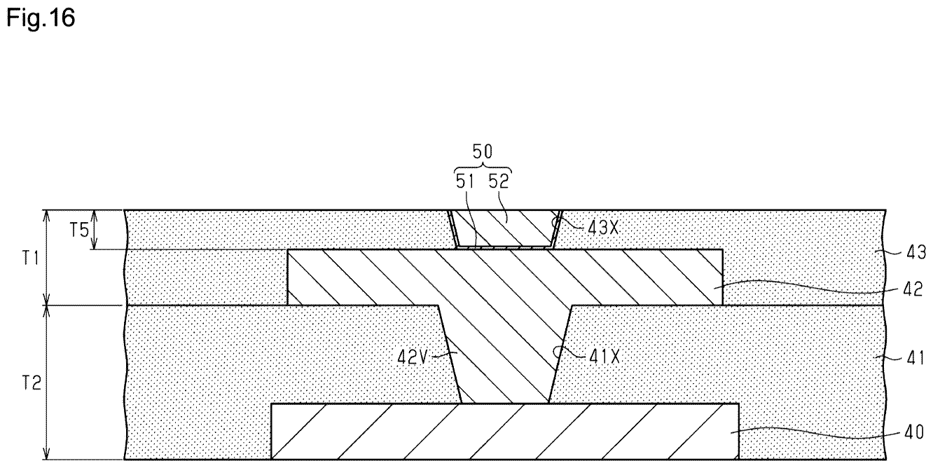

In the step illustrated in FIG. 16, a chemical mechanical polishing (CMP) process or the like is performed to polish the upper surface of the insulating layer 43 and the metal layer 52. In the present step, the upper surface of the insulating layer 43, the metal layer 52, and the seed layer 51 are polished until the thickness T1 of the insulating layer 43 becomes less than the thickness T2 of the insulating layer 41. This forms the via wiring 50 including the upper end surface that is flush with the upper surface of the insulating layer 43, as illustrated in FIG. 16. The via wiring 50 includes the seed layer 51, which covers the wall surface of the through hole 43X, and the metal layer 52, which is formed on the seed layer 51 and fills the through hole 43X. The via wiring 50 has the thickness T5 and the diameter of the upper end surface that are reduced by the polishing. Further, when the upper surface of the insulating layer 43 is polished, the upper surface of the insulating layer 43 is smoothed. For example, a roughness value Ra of the upper surface of the insulating layer 43 before the polishing may be approximately 300 nm to 400 nm, and a roughness value Ra of the upper surface of the insulating layer 43 after the polishing may be approximately 15 nm to 40 nm. In the present step, the upper surface of the insulating layer 43 and the upper end surface of the via wiring 50 become polished surfaces.

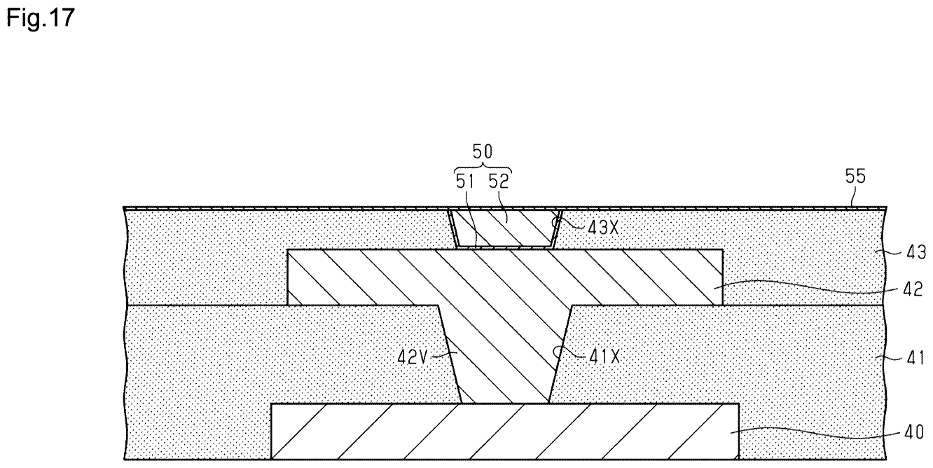

In the step illustrated in FIG. 17, the seed layer 55 is formed to cover the entire upper surface of the insulating layer 43 and the entire upper end surface of the via wiring 50. The seed layer 55 may be formed, for example, by a sputtering process or an electroless plating process. The seed layer 55 may be formed, for example, by the same process illustrated in FIG. 7.

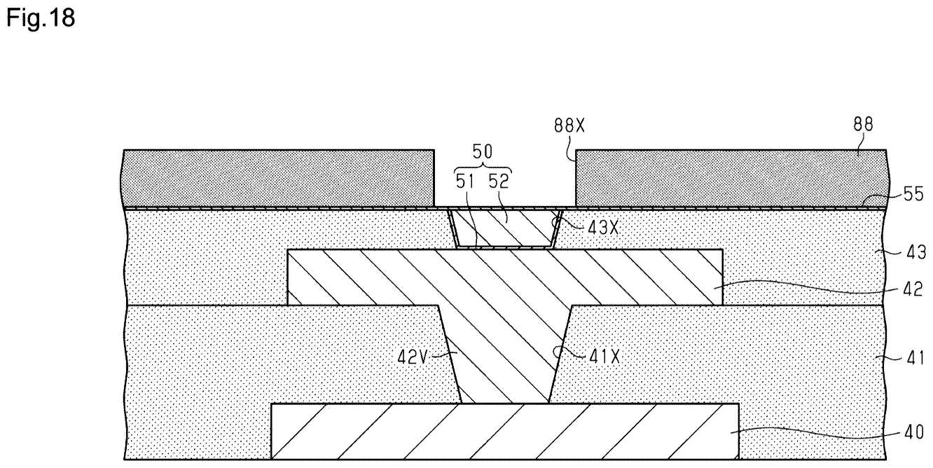

In the step illustrated in FIG. 18, a resist layer 88 including an opening pattern 88X at a given location is formed on the seed layer 55. The opening pattern 88X exposes parts of the seed layer 55 in correspondence with regions where the first electrode pads 54 are formed (refer to FIG. 14). The material of the resist layer 88 may be, for example, a material that is resistant to electrolytic plating performed in a subsequent process. For example, a photosensitive dry film resist or a liquid photoresist may be used as the resist layer 88. Examples of such a resist material include a novolac resin, an acrylic resin, or the like. The resist layer 88 may be formed, for example, by the same process illustrated in FIG. 8.

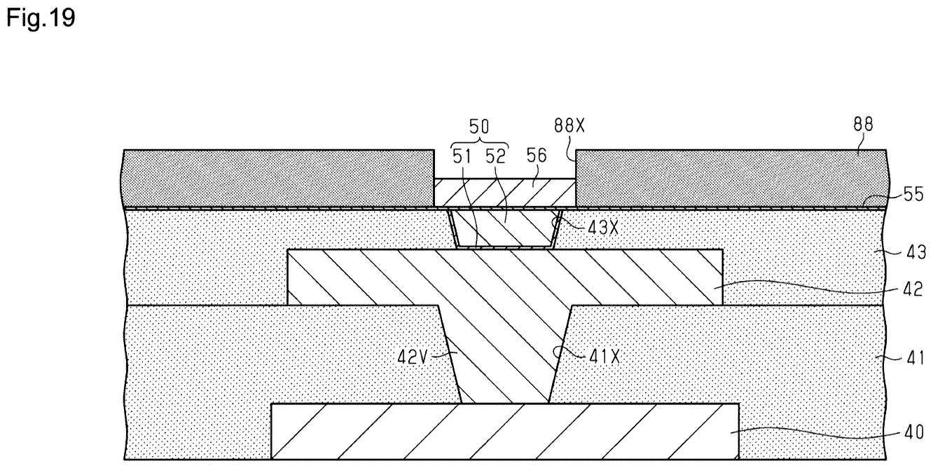

In the step illustrated in FIG. 19, electrolytic plating is performed on the seed layer 55 using the resist layer 88 as a plating mask and the seed layer 55 as a plating power feeding layer. That is, electrolytic plating (electrolytic Cu plating) is performed on the upper surface of the seed layer 55 exposed from the opening pattern 88X of the resist layer 88. The present step forms the metal layer 56 arranged in the opening pattern 88X.

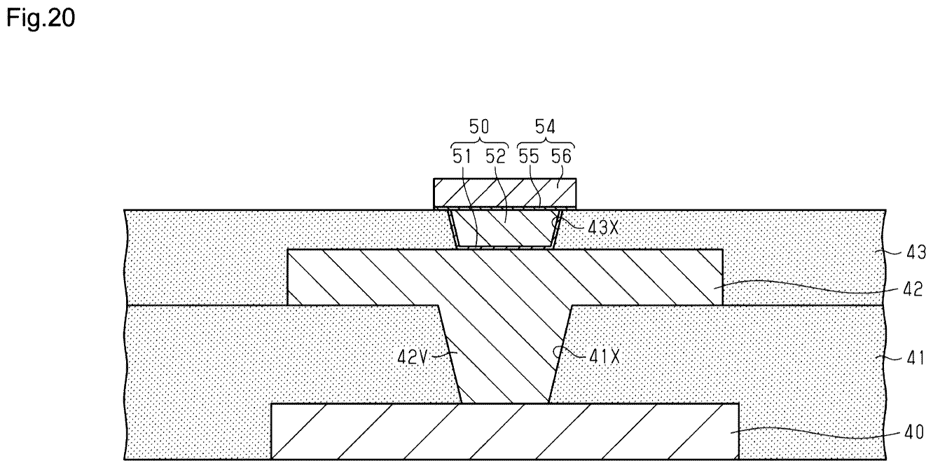

In the step illustrated in FIG. 20, the resist layer 88 in FIG. 19 is removed using an alkali stripping solution (e.g., organic amine stripping solution, caustic soda, acetone, or ethanol).

Subsequently, etching is performed using the metal layer 56 as an etching mask to remove unnecessary portions of the seed layer 55. The present step forms the first electrode pad 54, which includes the seed layer 55 and the metal layer 56, on the upper surface of the insulating layer 43 and the upper end surface of the via wiring 50.

The second embodiment has the following advantage in addition to the advantages (1) to (4) of the first embodiment.

(5) In the first wiring substrate 20A, CMP or the like is performed so that the insulating layer 43, which is the uppermost interlayer insulating layer of the first wiring substrate 20A, becomes thinner than the insulating layer 41, which is another insulating layer of the first wiring substrate 20A. Accordingly, the thickness T1 of the insulating layer 43 is less than the thickness of a single sheet of an insulating resin film. In this manner, the thickness T5 of the via wiring 50 extending through the insulating layer 43 in the thickness-wise direction readily becomes less than the thickness T4 of the via wiring 42V extending through the insulating layer 41 in the thickness-wise direction. This reduces the diameter of the via wiring 50, which in turn, allows for a reduction in the diameter of the first electrode pad 54 that is connected to the via wiring 50. As a result, the distance between the consecutive first electrode pads 54 may be sufficiently decreased.

### OTHER EMBODIMENTS

The above embodiments may be modified as described below. The above embodiments and the following modifications may be combined as long as the combined modifications remain technically consistent with each other.

The number of wiring layers, the wiring layout, or the like of the first wiring substrates 20 and 20A of the above embodiments may be modified in any manner. Further, the number of insulating layers of the first wiring substrates 20 and 20A may be modified in any manner.

In the above embodiments, the wiring layers 40 and 30 located above and below the core layer 21 are electrically connected to each other by the through-electrodes 22 that fill the through holes 21X of the core layer 21. Alternatively, the wiring layers 40 and 30 located above and below the core layer 21 may be electrically connected to each other, for example, by a through-hole plating layer formed on the wall of each through hole 21X. In this case, the through holes 21X including the through-hole plating layer may be filled with resin.

In the above embodiments, the solder resist layers 35 and 45 are each described as an example of a protective insulating layer that corresponds to an outermost insulating layer of the first wiring substrates 20 and 20A. However, such a protective insulating layer may be formed from any type of photosensitive insulating resin.

In the above embodiments, the solder resist layers 35 and 45 may be omitted.

In the above embodiments, a single second wiring substrate 60 is mounted on the first wiring substrates 20 and 20A. Alternatively, for example, multiple second wiring substrates 60 may be mounted on the first wiring substrates 20 and 20A.

The number of wiring layers, the wiring layout, or the like of the second wiring substrate 60 of the above embodiments may be modified in any manner. Further, the number of insulating layers of the second wiring substrate 60 may be modified in any manner. For example, the insulating layer 71 may be omitted.

In the above embodiments, the semiconductor chips 91 are mounted on the stacked wiring substrate 10. Alternatively, an electronic component other than the semiconductor chip 91, for example, an electronic component such as a chip component including a chip capacitor, a chip resistor, or a chip inductor, or a crystal oscillator may be mounted on the stacked wiring substrate 10.

Electronic components such as the semiconductor chip 91, a chip component, or a crystal oscillator may be mounted by any method (e.g., flip-chip mounting, wire bonding, solder bonding, or combination of these).

### CLAUSES

This disclosure further encompasses the following embodiments.

1. A method for manufacturing a stacked wiring substrate, the method including:
forming a first wiring substrate that includes a first electrode pad;
forming a second wiring substrate that includes a wiring structure having a wiring density that is higher than that of the first wiring substrate and a second electrode pad for connection to the first electrode pad; and
mounting the second wiring substrate on the first wiring substrate, where
the forming the first wiring substrate includes
   forming a first insulating layer that covers a first wiring layer,
   forming a second wiring layer on an upper surface of the first insulating layer, the second wiring layer being electrically connected to the first wiring layer,
   forming a second insulating layer on the upper surface of the first insulating layer to cover the second wiring layer, and
   forming the first electrode pad on an upper surface of the second insulating layer, the first electrode pad being electrically connected to the second wiring layer, and
the second insulating layer is formed so that a thickness of the second insulating layer is less than a thickness of the first insulating layer.

2. The method according to clause 1, where the forming the first electrode pad includes
forming a first through hole that extends through the second insulating layer in a thickness-wise direction and exposes part of an upper surface of the second wiring layer,
forming a metal layer that fills the first through hole and covers the upper surface of the second insulating layer,
polishing the metal layer and the upper surface of the second insulating layer to thin the second insulating layer and form third via wiring that fills the first through hole, the third via wiring including an upper end surface exposed from the second insulating layer, and
forming the first electrode pad to cover the upper surface of the thinned second insulating layer and the upper end surface of the third via wiring.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A stacked wiring substrate, comprising:
a first wiring substrate; and
a second wiring substrate mounted on the first wiring substrate, wherein
the first wiring substrate includes
a first wiring layer,
a first insulating layer covering the first wiring layer,
a second wiring layer stacked on an upper surface of the first insulating layer and electrically connected to the first wiring layer,
a second insulating layer stacked on the upper surface of the first insulating layer and covering the second wiring layer, and
a first electrode pad stacked on an upper surface of the second insulating layer and electrically connected to the second wiring layer,
the second wiring substrate includes
a wiring structure having a wiring density that is higher than that of the first wiring substrate, and
a second electrode pad connected to the first electrode pad, and
a thickness of the second insulating layer is less than a thickness of the first insulating layer.

2. The stacked wiring substrate according to claim 1, wherein
the second insulating layer includes a first through hole extending through the second insulating layer in a thickness-wise direction and exposing part of an upper surface of the second wiring layer, and
the first electrode pad is formed integrally with first via wiring that fills the first through hole.

3. The stacked wiring substrate according to claim 2, wherein
the first insulating layer includes a second through hole extending through the first insulating layer in the thickness-wise direction and exposing part of an upper surface of the first wiring layer,
the second wiring layer is formed integrally with second via wiring that fills the second through hole, and
the first via wiring has a size that is smaller than that of the second via wiring in plan view.

4. The stacked wiring substrate according to claim 1, wherein
a thickness of the second via wiring is greater than a thickness of the first wiring layer, and a thickness of the first via wiring is equal to or less than a thickness of the second wiring layer.

5. The stacked wiring substrate according to claim 1, wherein
the second insulating layer includes a first through hole extending through the second insulating layer in a thickness-wise direction and exposing part of an upper surface of the second wiring layer,
the first wiring substrate includes third via wiring filling the first through hole and including an upper end surface exposed from the second insulating layer,
the upper end surface of the third via wiring is flush with the upper surface of the second insulating layer, and
the first electrode pad is formed on the upper surface of the second insulating layer and the upper end surface of the third via wiring.

6. The stacked wiring substrate according to claim 5, wherein
the third via wiring includes
a first seed layer that covers an entire wall surface of the first through hole and the upper surface of the second wiring layer exposed from the first through hole, and
a first metal layer formed on the first seed layer and filling the first through hole, and
the first electrode pad includes
a second seed layer that covers the upper end surface of the third via wiring and the upper surface of the second insulating layer, and
a second metal layer formed on the second seed layer.

7. The stacked wiring substrate according to claim 5, wherein
the upper end surface of the third via wiring is a polished surface, and
the upper surface of the second insulating layer is a polished surface.

8. The stacked wiring substrate according to claim 5, wherein
the third via wiring has a size that is smaller than that of the second via wiring in plan view.

9. The stacked wiring substrate according to claim 5, wherein
a thickness of the second via wiring is greater than a thickness of the first wiring layer, and a thickness of the third via wiring is equal to or less than a thickness of the second wiring layer.

10. The stacked wiring substrate according to claim 1, wherein the first electrode pad has a size that is smaller than that of the second electrode pad in plan view.

11. A semiconductor device, comprising:
the stacked wiring substrate according to claim 1; and
a semiconductor chip mounted on the second wiring substrate.
